(19) United States
(12) Patent Application Publication
(10) Pub. No.: US 2020/0027767 A1
(43) Pub. Date: Jan. 23, 2020

(54) CARRIER, VACUUM SYSTEM AND METHOD OF OPERATING A VACUUM SYSTEM

(71) Applicant: Applied Materials, Inc., Santa Clara, CA (US)

(72) Inventors: Sebastian Gunther ZANG, Mainaschaff (DE); Andreas SAUER, Großostheim (DE)

(73) Assignee: Applied Materials, Inc., Santa Clara, CA (US)

(21) Appl. No.: 15/760,181

(22) PCT Filed: Mar. 17, 2017
(86) PCT No.: PCT/EP2017/056369

§ 371 Date: Mar. 14, 2018

(51) Int. Cl. H01L 21/677; C23C 14/04; C23C 14/24; C23C 14/50; H01F 7/02; H01F 13/00; H01F 7/20

(52) U.S. Cl. CPC H01L 21/67709; C23C 14/042; C23C 14/24; C23C 14/50; H01F 7/206; H01L 21/67718; H01F 7/02; H01F 13/003; H01L 21/67715

(57) ABSTRACT

A carrier for use in a vacuum system is described. The carrier includes: a magnet arrangement including one or more first permanent magnets; one or more second permanent magnets; and a magnet device configured to change a magnetization of the one or more first permanent magnets. The carrier may be used for carrying a mask device or a substrate in the vacuum system. Further, a vacuum system and a method of operating a vacuum system are described.

### TECHNICAL FIELD

Embodiments of the present disclosure relate to a carrier for use in a vacuum system, and particularly to a carrier for carrying a mask device or a substrate along a transportation path in a vacuum system. More specifically, a mask carrier or a substrate carrier for a vacuum deposition system is described. Further, a mask device for masked deposition on a substrate is described. Embodiments further relate to a vacuum system, particularly a vacuum system including a deposition apparatus for depositing an evaporated material on a substrate. Further embodiments relate to methods of operating a vacuum system.

### BACKGROUND

Opto-electronic devices that make use of organic materials are becoming increasingly popular for a number of reasons. Many of the materials used to make such devices are relatively inexpensive, so organic opto-electronic devices have the potential for cost advantages over inorganic devices. The inherent properties of organic materials, such as their flexibility, may be advantageous for applications such as for the deposition on flexible or inflexible substrates. Examples of organic opto-electronic devices include organic light emitting devices (OLEDs), organic phototransistors, organic photovoltaic cells, and organic photodetectors.

For OLEDs, the organic materials may have performance advantages over conventional materials. For example, the wavelength at which an organic emissive layer emits light may be readily tuned with appropriate dopants. OLEDs make use of thin organic films that emit light when a voltage is applied across the device. OLEDs are becoming an increasingly interesting technology for use in applications such as flat panel displays, illumination, and backlighting.

Materials, particularly organic materials, are typically deposited on a substrate in a vacuum system under sub-atmospheric pressure. During deposition, a mask device may be arranged in front of the substrate, wherein the mask device may have a plurality of openings that define an opening pattern corresponding to a material pattern to be deposited on the substrate, e.g. by evaporation. The substrate is typically arranged behind the mask device during deposition and is aligned relative to the mask device.

Carriers may be used for carrying the mask devices and/or the substrates in the vacuum system along mask and substrate transportation paths. For example, a mask carrier may be used to transport a mask device into a deposition chamber of the vacuum system, and a substrate carrier may be used to transport a substrate into the deposition chamber. Attaching and the detaching the mask devices and the substrates to and from carriers may be difficult and time-consuming. For example, the use of fixing elements such as screws for the attachment of the mask devices at the carriers may entail drawbacks, being time consuming and complicated, particularly under vacuum.

Accordingly, there is a need for a method and a system for quick and efficient mask and substrate handling in a vacuum system. In particular, simplifying and accelerating the mask and substrate transport and exchange using a carrier in a vacuum system would be beneficial.

### SUMMARY

In light of the above, a carrier for use in a vacuum system, a mask device, a vacuum system, and methods of operating a vacuum system are provided.

According to an aspect of the present disclosure, a carrier for use in a vacuum system is described. The carrier includes a magnet arrangement including one or more first permanent magnets, one or more second permanent magnets, and a magnet device configured to change a magnetization of the one or more first permanent magnets.

In some embodiments, the magnet arrangement is an electropermanent magnet arrangement.

According to a further aspect of the present disclosure, a mask device configured for masked deposition on a substrate is described. The mask device includes an electropermanent magnet arrangement.

According to a further aspect of the present disclosure, a vacuum system is described. The vacuum system includes a carrier transportation system configured for transporting a carrier along a carrier transportation path in the vacuum system, and a handover assembly configured to attach or detach a mask device or a substrate to or from a carrier with a magnet arrangement, particularly with an electropermanent magnet arrangement.

According to a further aspect of the present disclosure, a method of operating a vacuum system is described. The method includes transporting a carrier along a carrier transportation path in the vacuum system, while a mask device or a substrate is held at the carrier by a magnetic force generated by a magnet arrangement, particularly an electropermanent magnet arrangement.

Further aspects, advantages and features of the present disclosure are apparent from the description and the accompanying drawings.

### BRIEF DESCRIPTION OF THE D WINGS

So that the manner in which the above recited features of the present disclosure can be understood in detail, a more particular description of the present disclosure, briefly summarized above, may be had by reference to embodiments. The accompanying drawings relate to embodiments of the disclosure and are described in the following. Typical embodiments are depicted in the drawings and are detailed in the description which follows.

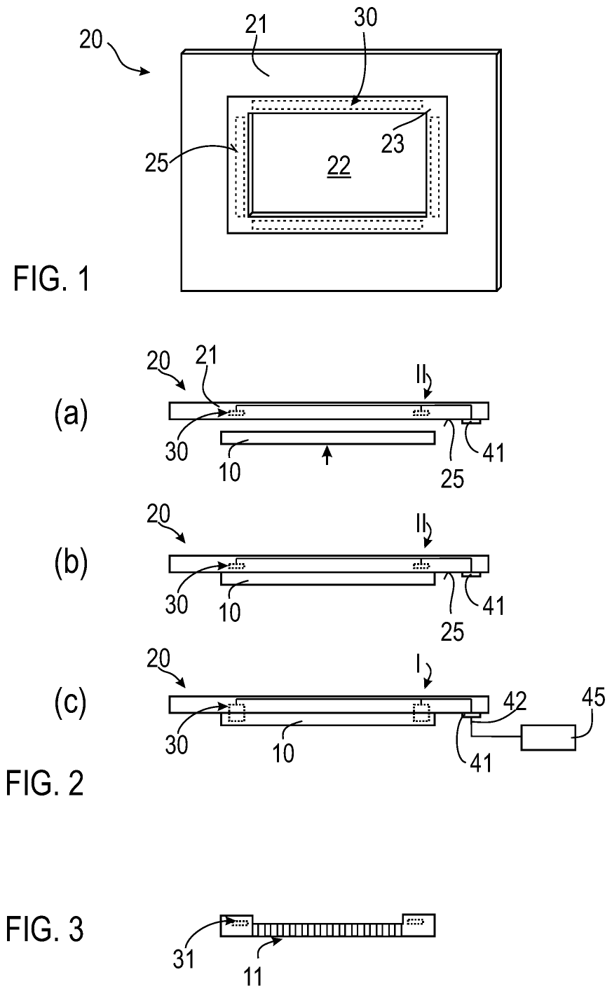

FIG. 1 is a schematic perspective view of a carrier for use in a vacuum system according to embodiments described herein;

FIG. 2 is a schematic illustration of subsequent stages (a), (b), (c) of a method of attaching a mask device to a carrier according to embodiments described herein;

FIG. 3 is a schematic view of a mask device according to embodiments described herein;

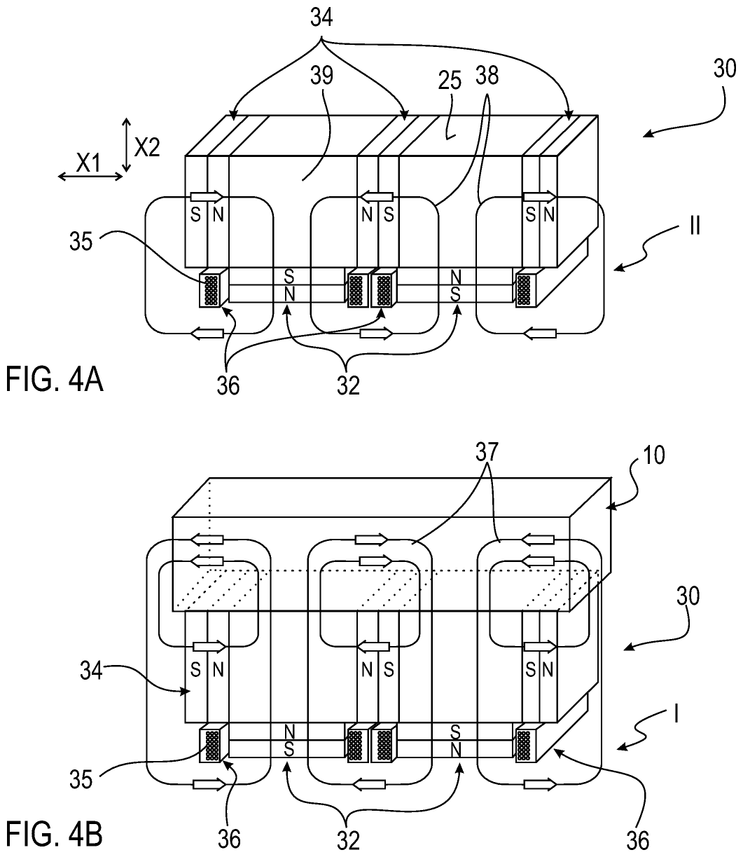

FIG. 4A is a schematic view of a magnet arrangement of a carrier according to embodiments described herein in a releasing state;

FIG. 4B is a schematic view of the magnet arrangement of FIG. 4A in a chucking state;

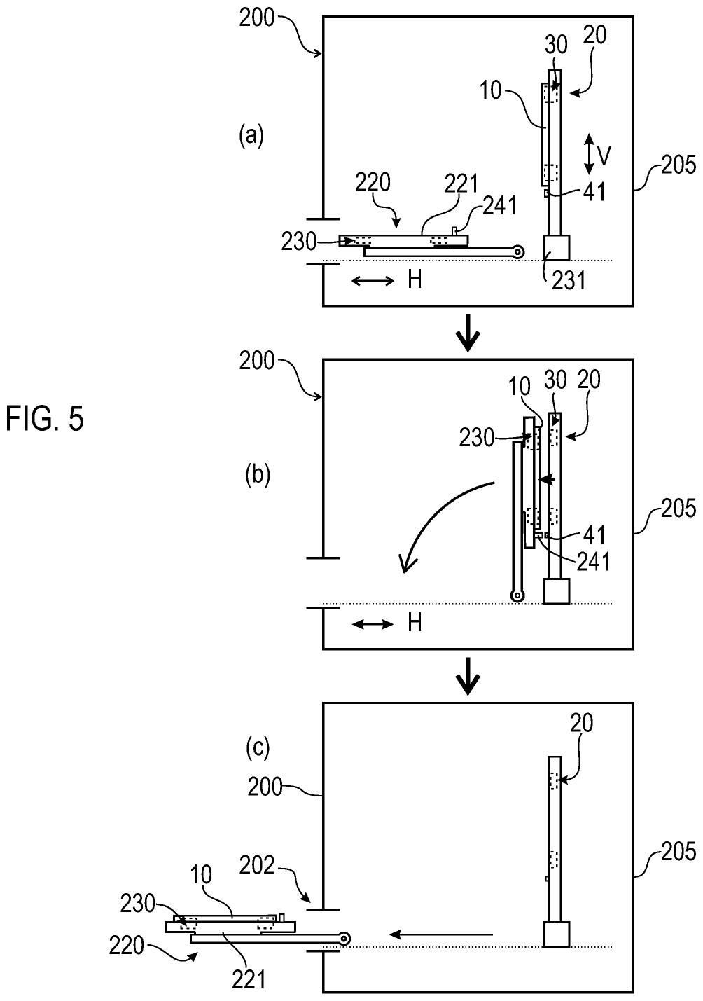

FIG. 5 is a schematic illustration of subsequent stages (a), (b), (c) of a method of operating a vacuum system according to embodiments described herein;

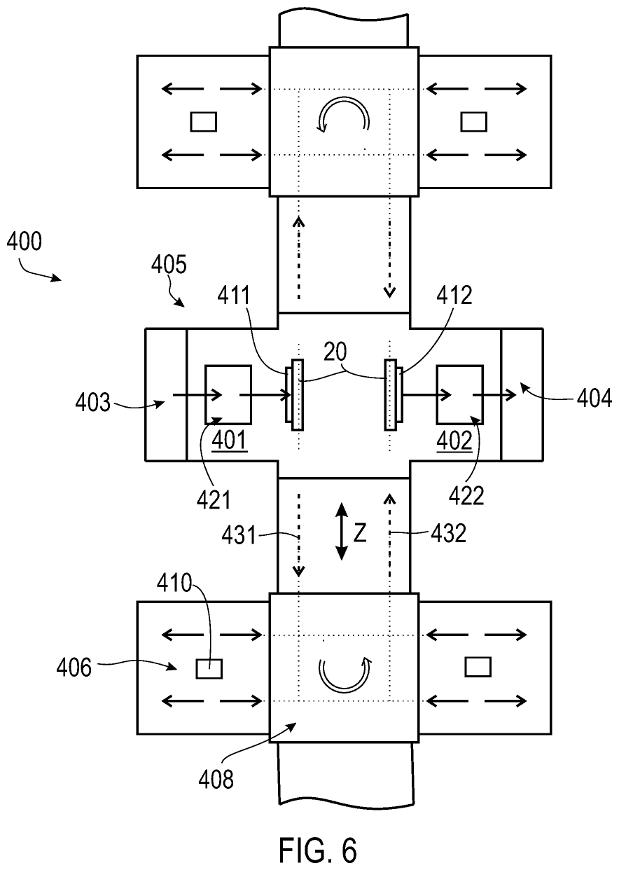

FIG. 6 is a schematic view of a vacuum system according to embodiments described herein;

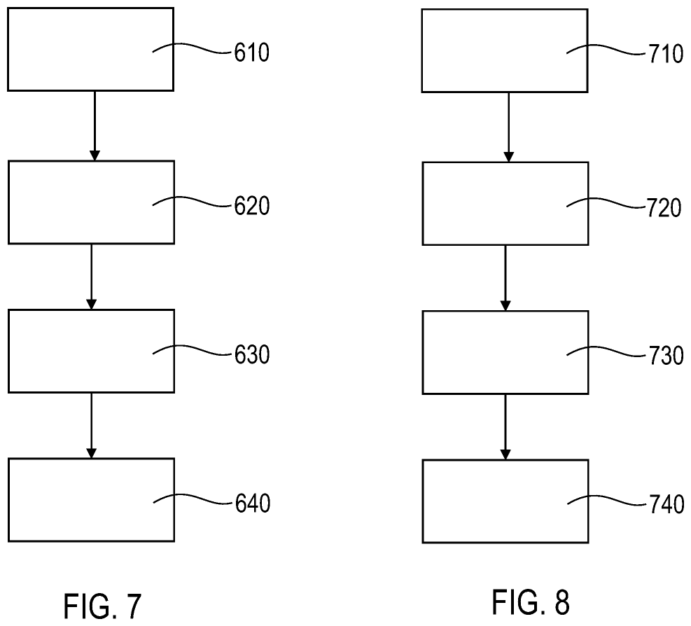

FIG. 7 is a flow diagram illustrating a method of operating a vacuum system according to embodiments described herein; and

FIG. 8 is a flow diagram illustrating a method of operating a vacuum system according to embodiments described herein.

### DETAILED DESCRIPTION OF EMBODIMENTS

Reference will now be made in detail to the various embodiments, one or more examples of which are illustrated in the figures. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

FIG. 1 is a schematic perspective view of a carrier 20 for use in a vacuum system according to embodiments described herein. A “carrier” as used herein may be understood as a device configured for carrying another device, e.g. a mask device or a substrate, in a vacuum system. In some embodiments, the carrier 20 is a mask carrier configured for carrying a mask device in the vacuum system. In some embodiments, the carrier 20 is a substrate carrier configured for carrying a substrate in a vacuum system. In the following, a mask carrier configured for carrying a mask device will be described in detail. However, it is to be noted that a carrier according to embodiments described herein may also be used for carrying a substrate or another device.

The carrier 20 may include a carrier body 21 with a holding surface 25, wherein the mask device can be held at the holding surface 25 of the carrier body 21.

In some embodiments, the carrier 20 is configured to be transported along a transportation path in the vacuum system. For example, the carrier 20 may be guided along tracks in a vacuum system and may include a guided portion that engages with the tracks. In some embodiments, the carrier 20 can be transported along the transportation path into a deposition chamber with a deposition source and/or out of the deposition chamber. In particular, the carrier 20 may be used to transport a mask device or a substrate into and out of a deposition chamber of the vacuum system.

A carrier transportation system may be provided for transporting the carrier along the transportation path. The transportation system may include a holding device such as a magnetic levitation device configured for lifting at least a part of the weight of the carrier and/or a driving unit configured for moving the carrier along the transportation path. A small driving force of the driving unit may be sufficient for moving the carrier, when at least a part of the weight of the carrier is carried by the holding unit.

In some embodiments, which may be combined with other embodiments described herein, the carrier 20 may be configured for holding the mask device or the substrate in a non-horizontal orientation, particularly in an essentially vertical orientation.

An “essentially vertical orientation” as used herein may be understood as an orientation wherein an angle between a main surface of the mask device and the gravity vector is between +10° and −10°, particularly between 0° and −5°. In some embodiments, the orientation of the mask device may not be (exactly) vertical during transport and/or during deposition, but slightly inclined with respect to the vertical axis, e.g. by an inclination angle between 0° and −5°, particularly between −1° and −5°. A negative angle refers to an orientation of the mask device wherein the mask device is inclined downward. A deviation of the mask and substrate orientations from the gravity vector during the deposition may be beneficial and might result in a more stable deposition process, or a facing down orientation might be suitable for reducing particles on the substrate during deposition. However, also an exactly vertical orientation)(+/−1° of the mask device during transport and/or during deposition is possible.

Also a larger angle between the gravity vector and the mask device during transport and/or during deposition is possible. An angle between 0° and +/−80° may be understood as a “non-horizontal orientation” as used herein. Transporting the mask device in a non-horizontal orientation may save space and allow for smaller vacuum chambers.

The carrier 20 may be essentially vertically oriented at least temporarily during the transport. Holding a large area mask in an essentially vertical orientation is challenging, because the mask device may bend due to the weight of the mask, the mask device may slide down from the holding surface in the case of an insufficient grip force, and/or the mask device may move with respect to a substrate which may be arranged behind the mask device during the deposition.

The carrier 20 includes a holding device configured for holding the mask device or the substrate at the holding surface 25 of the carrier body 21. According to embodiments described herein, a magnet arrangement 30 may be provided for holding the mask device. The magnet arrangement 30 is configured to generate a magnetic force for attracting the mask device toward the holding surface 25.

As compared to mechanical holding devices such as screws or clamps, providing a magnet arrangement 30 for holding the mask device with a magnetic force may be beneficial because attaching and detaching the mask device from the carrier may be possible in an easy and quick way. The tightening of mechanical holding devices such as screws may lead to small particles in the vacuum system, e.g. due to the friction between the screw and the thread or the attachment surfaces. These small particles may negatively affect the vacuum conditions in the vacuum system and may impair the deposition result. A connection with clamps may be comparably easy to handle, however, the attachment with clamps may be less reliable, particularly when attaching mask devices having a variable weight.

Using a magnetic force for the attachment of the mask device may be beneficial because the generation of small particles is reduced and the deposition result can be improved. Further, the mask device or the substrate can be easily detached by reducing or deactivating the magnetic force. Mask and substrate handling can be simplified and accelerated.

In particular, according to embodiments described herein, the magnet arrangement 30 includes permanent magnets for generating the magnetic force. As compared to electromagnets, permanent magnets may be beneficial because permanent magnets generate a magnetic force without an electrical power supply. The weight and the complexity of the carrier can be reduced, as no large batteries or power supplies may be provided on the carrier. Permanent magnets are also more reliable with regard to power failures. Further, electromagnets may heat up during use which may lead to a local thermal expansion of the mask device. The deposition may be negatively affected. A magnet arrangement with permanent magnets for generating the magnetic force may be lightweight and may allow for an accurate deposition.

According to embodiments described herein, the magnet arrangement 30 includes one or more first permanent magnets, one or more second permanent magnets, and a magnet device configured to change a magnetization of the one or more first permanent magnets. In particular, the magnet arrangement may include an electropermanent magnet arrangement.

Electropermanent magnets may be provided for generating the magnetic force for holding the mask device at the carrier. In some embodiments, the magnet arrangement can be configured for generating a force of 10 N/cm² or more, particularly 50 N/cm² or more, more particularly 100 N/cm² or more. An electropermanent magnet arrangement may be activated in a quick manner and may provide for a reliable attachment. Further, as the magnetic holding force is generated by permanent magnets, the carrier can be made lightweight and easy to transport. Yet further, the deposition accuracy can be improved, as the heat generation of the electropermanent magnet arrangement may be negligible.

The attachment or the detachment of a mask device to or from a carrier with a magnet arrangement according to embodiments described herein can be performed very quickly, e.g. in a few seconds. Further, an automatic attachment and detachment, e.g. in a vacuum system, may be possible.

In some embodiments, which may be combined with other embodiments described herein, the carrier may include a carrier body 21, wherein the magnet arrangement 30 is attached to or integrated with the carrier body 21. For example, the magnet arrangement 30 may be connected to the carrier body 21 or arranged in an inner volume of the carrier body 21. The magnet arrangement 30 may be configured to hold a mask device or a substrate at the holding surface 25 of the carrier body 21, particularly in a non-horizontal orientation, more particularly in an essentially vertical orientation.

The carrier 20 may be configured for holding a mask device in front of a substrate during the deposition of a material on the substrate, particularly by evaporation. Evaporated material may be directed from a vapor source toward the substrate through a plurality of openings of the mask device. A material pattern corresponding to an opening pattern of the mask device can be deposited on the substrate.

In some embodiments, the carrier body 21 may be provided with an opening 22, as is schematically depicted in FIG. 1. The mask device may be supported on an edge 23 of the carrier body 21 which surrounds the opening 22 and may extend across the opening 22. In other words, the edge 23 of the carrier body 21 adjacent to the opening 22 may support the mask device on the carrier.

The magnet arrangement 30 may be provided at the edge 23 of the carrier body 21 which surrounds the opening 22. In particular, the magnet arrangement 30 may be integrated in the carrier body 21 adjacent to the opening 22. Accordingly, an edge of the mask device which is supported on the edge 23 of the carrier body 21 may be attracted toward the carrier body 21 via the magnet arrangement 30.

In some embodiments, the mask device may include a mask and a mask frame. The mask frame may stabilize the mask which is typically a delicate component. For example, the mask frame may surround the mask in the form of a frame. The mask may be permanently fixed to the mask frame, e.g. by welding, or the mask may be releasably fixed to the mask frame. A circumferential edge of the mask may be fixed to the mask frame.

The mask frame of the mask device may be supported on the edge 23 of the carrier body 21 which surrounds the opening 22, while the mask may extend across the opening 22 when the mask device is held at the carrier 20.

The mask may include a plurality of openings formed in a pattern and configured to deposit a corresponding material pattern on a substrate by the masked deposition process. During deposition, the mask may be arranged at a close distance in front of the substrate or in direct contact with the front surface of the substrate. For example, the mask may be a fine metal mask (FMM) with a plurality of openings, e.g. 100.000 openings or more. For example, a pattern of organic pixels may be deposited on the substrate. Other types of masks are possible, e.g. edge exclusion masks. The mask device may be configured for a masked evaporation process, wherein a material pattern is formed on a substrate by evaporation. The evaporated material may include organic compounds in some embodiments. For example, an OLED device may be manufactured.

In some embodiments, the mask device may be at least partially made of a metal, e.g. of a metal with a small thermal expansion coefficient such as invar. The mask frame may include a magnetic material so that the mask frame can be attracted to the carrier 20 by magnetic forces. Alternatively or additionally, also the mask may include a magnetic material so that the mask can be magnetically attracted toward the substrate during deposition, e.g. with a magnetic chucking device.

The mask device may have an area of 0.5 m² or more, particularly 1 m² or more. For example, a height of the mask device may be 0.5 m or more, particularly 1 m or more, and/or a width of the mask device may be 0.5 m or more, particularly 1 m or more. A thickness of the mask device may be 1 cm or less, wherein the mask frame may be thicker than the mask. Therefore, in some embodiments, the opening 22 of the carrier 20 may have an area of 0.5 m² or more, particularly 1 m² or more. In particular, the opening 22 of the carrier 20 may be slightly smaller than the mask device so that the mask frame can be supported on the edge 23 of the carrier body surrounding the opening 22.

FIG. 2 is a schematic illustration of subsequent stages (a), (b), (c) of a method of attaching a mask device 10 to a carrier 20 according to embodiments described herein. The carrier 20 may be similar to the carrier depicted in FIG. 1, so that reference can be made to the above explanations, which are not repeated here.

The carrier 20 includes a carrier body 21 with a holding surface 25. A magnet arrangement 30 is provided at the carrier body 21 and configured for attracting the mask device 10 toward the holding surface 25 of the carrier body 21.

In stage (a) of FIG. 2, the mask device 10 is moved toward the holding surface 25 of the carrier 20.

In some embodiments, which may be combined with other embodiments described herein, the magnet arrangement 30 may be switchable between a chucking state I and a releasing state II. In the releasing state II, the magnet arrangement may generate no external magnetic field or a small external magnetic field at the holding surface 25. In the chucking state I, the magnet arrangement 30 may generate a strong external magnetic field at the holding surface. In other words, a second external magnetic field at the holding surface in the releasing state II may be smaller than a first external magnetic field at the holding surface in the chucking state I.

In stage (a) of FIG. 2, the magnet arrangement 30 is provided in the releasing state II in which the magnet arrangement may generate no external magnetic field or only a small external magnetic field at the holding surface 25. Accordingly, the mask device 10 is not attracted toward the holding surface 25.

In stage (b) of FIG. 2, the mask device 10 has moved in contact with the carrier 20. The magnet arrangement 30 is still in the releasing state II in which the mask device 10 is not held at the holding surface by a magnetic force of the magnet arrangement.

In stage (c) of FIG. 2, the magnet arrangement 30 has switched to the chucking state I. In the chucking state I, the magnetic field generated by the magnet arrangement 30 holds the mask device 10 at the holding surface of the carrier 20. The carrier 20 can then be transported along a transportation path in the vacuum system together with the mask device 10.

Similarly, the mask device 10 can be detached from the carrier 20 by switching the magnet arrangement 30 from the chucking state I to the releasing state II in which no external magnetic field or only a small external magnetic field is generated at the holding surface, as is depicted in stage (b) of FIG. 2. The mask device 10 can then be removed from the carrier 20.

The magnet arrangement 30 may be switched between the releasing state I and the chucking state II by changing a direction of magnetization of the one or more first permanent magnets of the magnet arrangement 30, e.g. by an electric pulse provided to the magnet device of the magnet arrangement. In particular, a polarity of the one or more first permanent magnets may be reversed by an electric pulse sent to the magnet device.

In some embodiments, the carrier 20 includes a power supply, e.g. a battery, for generating electric pulses for changing the magnetization of the one or more first permanent magnets. In other embodiments, the carrier may not include a power supply for the magnet arrangement. The weight of the carrier can be reduced.

In some embodiments, the carrier 20 may include a first electrical contact 41 which is electrically connected to the magnet arrangement 30. The first electrical contact 41 can be contacted with a second electrical contact 42 connected to a power supply 45. The power supply 45 may be an external power supply that is not attached to or integrated into the carrier 20. The power supply 45 may generate an electric pulse, e.g. a current pulse, which may be suitable for changing the magnetization of the one or more first permanent magnets. For example, an output terminal of the power supply 45 may be electrically connected to the second electrical contact 42, as is schematically depicted in stage (c) of FIG. 2. The second electrical contact 42 may be brought into contact with the first electrical contact 41 of the carrier, in order to switch between the chucking state I and the releasing state II of the magnet arrangement 30. After switching, the second electrical contact 42 may be removed from the first electrical contact 41, and the carrier 20 can be transported away from the power supply 45.

In particular, the first electrical contact 41 of the carrier 20 may be exposed at a surface of the carrier, such as to be easily connectable to the power supply 45 via the second electrical contact 42 when the carrier is in a position for attachment or detachment of a mask device 10. In some embodiments, the first electrical contact 41 may be arranged at the holding surface 25 of the carrier body 21. An electric connection, such as wires extending in the carrier body 21, may be connected between the first electrical contact 41 and the magnet device of the magnet arrangement. Accordingly, a winding of the magnet device can be provided with a current pulse via the first electrical contact 41.

According to a further aspect described herein, a mask device 11 for masked deposition on a substrate is described, wherein the mask device 11 includes an electropermanent magnet arrangement 31. A mask device 11 according to embodiments described herein is schematically shown in FIG. 3.

For example, the electropermanent magnet arrangement 31 may be attached to or integrated into a mask frame of the mask device 11. When the mask device 11 includes the electropermanent magnet arrangement 31, attaching and detaching the mask device from a holding surface may be easily possible by activating the electropermanent magnet arrangement 31 of the mask device with an electric pulse. The mask device 11 may have an electrical contact for providing the electropermanent magnet arrangement 31 with an electric pulse for switching.

Mask handling can be simplified and accelerated, as the mask device can be easily attached to and detached from various magnetic surfaces, e.g. for transport, deposition and/or storage.

FIG. 4A is a schematic view of a magnet arrangement 30 for a carrier according to embodiments described herein in a releasing state II. FIG. 4B is a schematic view of the magnet arrangement 30 of FIG. 4A in a chucking state I in which a device, e.g. a mask device 10, is held by the magnet arrangement 30. The magnet arrangement 30 can be integrated into a carrier according to any of the embodiments described herein.

The magnet arrangement 30 may be configured as an electropermanent magnet arrangement. An electropermanent magnet arrangement includes one or more first permanent magnets 32, one or more second permanent magnets 34, and a magnet device 36.

An electropermanent magnet arrangement (or “EPM”) as used herein may be understood as a magnet arrangement, in which a magnetic field generated by permanent magnets can be changed by an electric pulse, particularly by a current pulse in a winding of a magnet device. In particular, the magnetic field may be switched on or off on one side of the magnet arrangement where the holding surface 25 is provided. Electropermanent magnets may work based on the double magnet principle. The one or more first permanent magnets 32 may consist of a “soft” or “semi-hard” magnetic material, i.e. a material with a low coercivity. The one or more second permanent magnets 34 may consist of a “hard” magnetic material, i.e. a material with a higher coercivity. The direction of magnetization of the first permanent magnets 32 can be changed by an electric pulse provided to the magnetic device. As an example, a polarity of the one or more first permanent magnets 320 can be reversible by the electric pulse. The direction of magnetization of the one or more second permanent magnets 34 may remain constant due to the high coercivity of the respective material.

The polarity of the one or more first permanent magnets and the polarity of the one or more second permanent magnets are magnetic polarities, i.e., magnetic south poles and magnetic north poles.

According to some embodiments, a duration of the electric pulse to change the magnetization of the one or more first permanent magnets may be 0.1 seconds or more, specifically 1 second or more and/or 5 seconds or less. As an example, the duration of the electric pulse may be in a range between 0.1 s and 10 s, specifically in a range between 0.5 s and 5 s, and more specifically in a range between 1 s and 2 s.

In some embodiments, the magnet device 36 may include a winding 35, e.g. a wire winding or solenoid that is provided at least partially around the one or more first permanent magnets 32. By supplying an electric pulse through the winding 35, a local magnetic field at the position of the one or more first permanent magnets 32 is generated which changes the magnetization of the one or more first permanent magnets 32. In particular, a polarity of the one or more first permanent magnets 32 may be reversed by feeding a current pulse through the winding 35 of the magnet device 36.

In some embodiments, a plurality of first permanent magnets 32 is provided, wherein the first permanent magnets 32 are at least partially surrounded by windings 35 of the magnet device 36. For example, in the embodiment of FIG. 4A, two first permanent magnets 32 are depicted, wherein a wire winding extends around each of the two first permanent magnets 32. More than two first permanent magnets may be arranged next to each other. In some embodiments, the polarities of two adjacent first permanent magnets directed toward the holding surface 25 may be opposite polarities, respectively. Accordingly, the magnetic field lines may form one or more loops wherein each loop penetrates through adjacent first permanent magnets in opposite directions.

In some embodiments, a plurality of second permanent magnets 34 is provided. For example, in the embodiment of FIG. 4A, three second permanent magnets 34 are depicted. Two, three or more second permanent magnets may be provided, e.g. one after the other in a row arrangement. The second permanent magnets may be arranged such that poles of opposite polarities of adjacent second permanent magnets may be directed toward each other. Accordingly, the magnetic field lines do not linearly extend through the row of second permanent magnets, but a plurality of separate loops may form due to the opposite poles facing each other.

In some embodiments, the one or more first permanent magnets 32 may be arranged in a first plane, and the one or more second permanent magnets 34 may be arranged in a second plane. The second plane may be closer to the holding surface 25 than the first plane. Accordingly, the one or more second permanent magnets 34 may be arranged closer to the holding surface 25 than the one or more first permanent magnets 32.

In some embodiments, the one or more first permanent magnets 32 may have a first orientation and the one or more second permanent magnets 34 may have a second orientation different from the first orientation. In particular, the first orientation and the second orientation may be perpendicular. For example, the one or more first permanent magnets 32 may be oriented in a horizontal direction or plane and the one or more second permanent magnets 34 may be oriented in a vertical direction or plane.

In some embodiments, the magnetic field generated by the second permanent magnets 34 may have a first main orientation X1 which can be essentially parallel to the holding surface 25. The magnetic field generated by the first permanent magnets 32 may have a second main orientation X2 which can be essentially perpendicular to the holding surface 25. Accordingly, by reversing the polarities of the first permanent magnets 32, the resultant total magnetic field may change in a direction perpendicular to the holding surface, i.e. toward an interior of the carrier body or toward an exterior of the carrier body. By switching the magnet arrangement from the releasing state II of FIG. 4A to the chucking state I of FIG. 4B, the resultant overall magnetic field can be shifted to an exterior of the holding surface 25 such as to penetrate into a device to be attached. In particular, in the chucking state I, opposite poles of the one or more first permanent magnets and of the one or more second permanent magnets may be facing each other such that the magnetic field lines may be urged toward an outer environment of the carrier where the device to be attached is arranged.

The external magnetic field 37 which penetrates from the carrier into a mask device 10 is schematically depicted in FIG. 4B. The external magnetic field 37 remains in the mask device 10 until the polarity of the first permanent magnets 32 is reversed by an electric pulse. The chucked mask device can be released by providing an electric pulse to the magnet device 36. A reliable attachment of the mask device can be obtained also in case of a power failure, because the mask device is held by a magnetic force generated by permanent magnets. In the chucking state I, no external power may be used for maintaining the chucked state. A bistable magnet arrangement can be provided which remains in the releasing state II or in the chucking state I after switching. The switching can be performed automatically in some embodiments.

The internal magnetic field 38 that is generated by the magnet arrangement 30 in the releasing state II is schematically depicted in FIG. 4A.

A core 39 such as a steel core may be provided for increasing the magnetic field strength, e.g. between adjacent second permanent magnets, respectively.

In some embodiments, which may be combined with other embodiments described herein, the one or more first permanent magnets 32 include a soft or semi-hard magnetic material, and/or the one or more second permanent magnets 34 include a hard magnetic material. For example, the one or more first permanent magnets 32 may include AlNiCo and/or the one or more second permanent magnets 34 may include neodymium. In particular, the one or more first permanent magnets 32 may be AlNiCo-magnets, and/or the one or more second permanent magnets 34 may be neodymium-magnets. Other magnets with low and high coercivities may be used. For example, the hard magnetic material may have a coercivity of 1.000 kA/m or more, particularly 10.000 kA/m or more, and/or the soft magnetic material may have a coercivity of 1.000 kA/m or less, particularly 100 kA/m or less.

FIG. 5 shows subsequent stages (a), (b), (c) of a method of operating a vacuum system 200 according to embodiments described herein. The vacuum system 200 may include one or more vacuum chambers, e.g. one or more deposition chambers, one or more routing modules, one or more transition chambers, a mask handling chamber and/or further vacuum chambers.

The vacuum system 200 includes a carrier transportation system configured for transporting a carrier 20 along a carrier transportation path in the vacuum system 200. A carrier track 231 is schematically depicted in FIG. 5, wherein the carrier transportation system may be configured for transporting carriers along the carrier track 231.

The carrier 20 may be a carrier according to any of the embodiments described herein. In particular, the carrier 20 may include a magnet arrangement 30 as described herein, particularly an electropermanent magnet arrangement.

In some embodiments, a mask device 10 or a substrate may be attached or detached from the carrier 20 outside the vacuum system, e.g. under atmospheric pressure. For example, by applying an electric pulse to the magnet arrangement 30 of the carrier, the magnet arrangement may be switched between the releasing state and the chucking state for attaching or detaching the mask device or the substrate to or from the carrier.

In some embodiments, a mask device 10 or a substrate may be attached or detached from the carrier in the vacuum system 200, particularly under sub-atmospheric pressure, e.g. at a background pressure of 10 mbar or less. A handover assembly 220 configured to attach or detach a mask device 10 or a substrate to or from the carrier 20 may be arranged in a vacuum chamber 205 of the vacuum system 200, e.g. in a mask handling chamber.

The handover assembly 220 may be configured for attaching the mask device 10 to the carrier 20 by controlling the state of the magnet arrangement 30 of the carrier. For example, the handover assembly 220 may apply an electric pulse to the magnet arrangement 30 for switching from the releasing state to the chucking state.

The handover assembly 220 may be configured for detaching the mask device 10 from the carrier 20 by controlling the state of the magnet arrangement 30 of the carrier. For example, the handover assembly 220 may apply an electric pulse to the magnet arrangement 30 for switching from the chucking state to the releasing state.

In some embodiments, which may be combined with other embodiments described herein, the handover assembly 220 may include a second electrical contact 241 configured for contacting a first electrical contact 41 of the carrier 20 for activating the magnet arrangement 30 of the carrier 20. In particular, the first electrical contact 41 may be exposed at a surface of the carrier, and the second electrical contact 241 may be exposed at a surface of the handover assembly 220. The first electrical contact 41 and the second electrical contact 241 may come into contact when the handover assembly 220 is in a position for attaching or detaching the mask device 10 from the carrier.

In some embodiments, the handover assembly 220 may include a power supply for generating electric pulses for switching the state of the magnet arrangement 30. In a position for attaching or detaching the mask device 10 from the carrier, an output terminal of the power supply may be brought into contact with the first electrical contact 41 of the carrier. After the state switching, the carrier may move away from the power source, e.g. along the carrier track 231.

In some embodiments, which may be combined with other embodiments described herein, the handover assembly 220 may include a second magnet arrangement 230, particularly a second electropermanent magnet arrangement, configured to hold a mask device 10 or a substrate at a holding portion 221 of the handover assembly 220.

For example, when detaching the mask device 10 from the carrier with the magnet arrangement 30 of the carrier 20, the mask device may be attached to the holding portion 221 of the handover assembly 220 with the second magnet arrangement 230 of the handover assembly. Further, when attaching the mask device 10 to the carrier with the magnet arrangement 30 of the carrier, the mask device may be detached from the holding portion 221 of the handover assembly 220 with the second magnet arrangement 230.

In particular, the handover assembly 220 may include a power supply for controlling the state of the magnet arrangement 30 of the carrier and/or the state of the second magnet arrangement 230 of the handover assembly. Mask processing can be simplified and accelerated. Further, the attachment and detachment of mask devices from carriers under vacuum can be automatized.

In some embodiments, the second magnet arrangement 230 may be an electropermanent magnet as depicted in FIG. 4A. Alternatively, the second magnet arrangement may include electromagnets for holding the mask device at the handover assembly by a magnetic force generated by electromagnets. Other gripping arrangements are possible, e.g. mechanical gripping arrangements.

As is depicted in stage (a) of FIG. 5, the mask device 10 may be provided in the vacuum system 200, and the mask device 10 is held by a carrier 20 in a non-horizontal orientation V, particularly in an essentially vertical orientation. The mask device 10 can be transported between the vacuum chambers of the vacuum system 200 while being held at the carrier 20. In some embodiments, the mask device 10 may be a used mask device that is to be unloaded from the vacuum system, e.g. for cleaning or exchange. For example, the mask device may have been used for the deposition on a substrate in a deposition chamber, and may be transported from the deposition chamber to the vacuum chamber 205 along a transportation path.

According to embodiments described herein, the mask device 10 is detached from the carrier 20 in the vacuum system 200 under vacuum. The detachment of the mask device 10 from the carrier 20 is schematically depicted in stage (b) of FIG. 5.

The handover assembly 220 with the holding portion 221 may be provided for detaching the mask device 10 from the carrier 20 under vacuum. The handover assembly 220 may include a robot device such as a robot arm. The handover assembly 220 may be configured for releasing a magnetic connection between the mask device 10 and the carrier 20. During transport, the mask device may be held at the carrier by a magnetic force generated by the magnet arrangement 30 of the carrier. The handover assembly 220 may be configured for deactivating the gripping force of the magnet arrangement 30 and for gripping the mask device with an own gripping force.

In some embodiments, which may be combined with other embodiments described herein, the mask device 10 is detached from the carrier 20 while the mask device 10 is held by the carrier 20 in a non-horizontal orientation V, particularly in an essentially vertical orientation. For example, the mask device 10 is handed over from the carrier 20 to the holding portion 221 of the handover assembly 220 while the mask device 10 is in an essentially vertical orientation. The orientation of the carrier can therefore remain essentially constant during transport and mask detachment.

After detaching the mask device 10 from the carrier 20, the mask device 10 can be unloaded from the vacuum system 200.

For example, as is schematically depicted in stage (c) of FIG. 5, unloading may include moving the mask device 10 out of the vacuum system 200 along a mask unloading passage which may extend through a wall of the vacuum system. In some embodiments, the mask device 10 may be moved through a closable opening 202 provided in a side wall of the vacuum chamber 205. The mask device 10 may be unloaded from the vacuum system via a load lock chamber (not shown in FIG. 5). Unloading the mask device 10 from the vacuum chamber via the load lock chamber may be beneficial because there may be no need to flood the vacuum chamber 205. Rather, flooding of the load lock chamber may be sufficient. The handover assembly 220 may put the detached mask device into a mask magazine which may be provided in the load lock chamber. The closable opening 202 may be closed when the mask device is arranged in the load lock chamber, and the load lock chamber can be flooded, while the vacuum chamber may remain under sub-atmospheric pressure. Thereupon, the mask device 10 may be taken out of the load lock chamber, e.g. by a lifting device.

The mask device 10 may be detached from the carrier 20 in the vacuum system 200. Accordingly, only the mask device 10 may be brought out of the vacuum system 200, whereas the carrier 20 can remain in the vacuum system 200.

In some embodiments, the mask device 10 is moved out of the vacuum system 200, while the mask device 10 is in a second orientation H different from the non-horizontal orientation V. The second orientation H may be an essentially horizontal orientation in some embodiments. For example, the mask device 10 may be translated through the closable opening 202 out of the vacuum chamber 205, while the mask device is in the essentially horizontal orientation. An “essentially horizontal orientation” as used herein may be understood as an orientation in which an angle between the main surface of the mask device and a horizontal plane is 30° or less, particularly 20° or less, more particularly 10° or less, or wherein the mask device is arranged exactly horizontally (+/−1°).

As is schematically depicted in stage (c) of FIG. 5, the mask device 10 may be moved out of the vacuum chamber 205 along an essentially linear transport path which may be a horizontal path, while the mask device 10 is arranged in an essentially horizontal orientation. For example, the handover assembly 220 may be configured for a movement, particularly for a translational movement, of the holding portion 221 through the closable opening 202.

In some embodiments, which may be combined with other embodiments described herein, the mask device 10 may be rotated from the non-horizontal orientation V to the second orientation H, before the mask device 10 is unloaded from the vacuum system 200. For example, the mask device may be detached from the carrier 20 in an essentially vertical orientation, may then be rotated from the essentially vertical orientation to the second orientation H, and may then be unloaded from the vacuum system while the mask device is in the second orientation H. Mask exchange can be accelerated.

The handover assembly 220 may be configured for attaching the mask device 10 to the carrier 20, for detaching the mask device from the carrier 20, for rotating the mask device between the non-horizontal orientation and the second orientation, as well as for moving the mask device along a linear movement path. In some embodiments, the handover assembly 220 includes a robot device such as a robot arm which is configured to grip the mask device, to rotate (or to swing) the gripped mask device around a rotation axis and to linearly translate the mask device.

In some embodiments, the handover assembly 220 may grip and release the mask device 10 with a second magnet arrangement 230 which may be an electropermanent magnet arrangement as depicted in FIG. 4A.

The stages (a), (b), (c) may be performed in an inverted sequence for loading a mask device 10 into the vacuum chamber 205 as well as for attaching the mask device 10 to a carrier 20.

FIG. 6 is a schematic top view of a vacuum system 400 according to embodiments described herein. The vacuum system may be configured for depositing one or more materials on a substrate, e.g. by evaporation.

The vacuum system 400 includes a vacuum chamber 405, at least one deposition chamber 406, and a carrier transportation system configured for transporting carriers 20 in a non-horizontal orientation V between the vacuum chamber 405 and the at least one deposition chamber 406.

The vacuum chamber 405 may include a first mask handling area 401 with a first handover assembly 421 configured for handling mask devices to be used 411 and a second mask handling area 402 with a second handover assembly 422 configured for handling used mask devices 412.

“Mask devices to be used” as used herein may be understood as mask devices that are to be transported into at least one deposition chamber to be used for masked deposition on a substrate. In some embodiments, a mask device to be used may be a new mask device, a cleaned mask device or a mask device that has undergone service or maintenance.

“Used mask devices” as used herein can be understood as mask devices that have been used for masked deposition in a deposition chamber. The used mask devices are to be transported out of the deposition chamber, e.g. for cleaning or maintenance. For example, the used mask devices are to be unloaded from the vacuum system, e.g. for cleaning under atmospheric pressure. By using a mask device for masked deposition on one or more substrates, a mask device to be used becomes a used mask device. Typically, a mask device is used for masked deposition on ten or more substrates, whereupon the mask device may be cleaned. After cleaning, the mask device can be loaded again into the vacuum system to be used for masked deposition.

The second mask handling area 402 and the first mask handling area 401 may correspond to different sections of the vacuum chamber 405 that may be adjacent to each other or that may be spaced apart from each other. For example, the first mask handling area 401 and the second mask handling area 402 may be opposite parts of the vacuum chamber. In some embodiments, the first mask handling area 401 and the second mask handling area 402 are located on opposite sides of carrier transport paths configured for the transport of the carriers 20. For example, as is schematically depicted in FIG. 6, the first mask handling area 401 may be located on a first side of first and second tracks and the second mask handling area 402 may be located on the opposite side of the first and second tracks.

According to some embodiments described herein, the mask devices to be used 411 can be handled, e.g. attached, detached, loaded, unloaded, stored, moved, rotated and/or translated, separately from the used mask devices 412. A contamination of cleaned mask devices can be reduced or avoided.

A mask loading passage may extend to the first mask handling area 401 and may be configured for loading the mask devices to be used 411 into the vacuum system 400, e.g. via a first load lock chamber 403. A mask unloading passage may extend from the second mask handling area 402 and may be configured for unloading the used mask devices 412 from the vacuum system 400, e.g. via a second load lock chamber 404. In some embodiments, the mask loading passage extends via a first load lock chamber 403 into the first mask handling area 401. A first closable opening may be provided between the first mask handling area 401 and the first load lock chamber 403. The mask unloading passage may extend from the second mask handling area 402 via a second load lock chamber 404. A second closable opening may be provided between the second mask handling area 402 and the second load lock chamber 404.

The first load lock chamber 403 and the second load lock chamber 404 may be provided adjacent to the vacuum chamber 405 on two opposite sides of the vacuum chamber 405.

In some embodiments, which may be combined with other embodiments described herein, the first handover assembly 421 may be configured for attaching the mask devices to be used 411 to carriers 20. For example, the first handover assembly 421 may be similar to the handover assembly 220 shown in FIG. 5, so that reference can be made to the above explanations which are not repeated here. The second handover assembly 422 may be configured for detaching the used mask devices 412 from the carriers 20. The second handover assembly 422 may be similar to the handover assembly 220 shown in FIG. 5, so that reference can be made to the above explanations which are not repeated here.

The complexity of the carrier traffic in the vacuum system may be reduced by providing a carrier transportation system that includes a first track 431 for guiding carriers 20 that hold mask devices to be used 411 from the first mask handling area 401 toward the at least one deposition chamber 406, and/or that includes a second track 432 for guiding carriers 20 that hold used mask devices 412 to the second mask handling area 402 from the at least one deposition chamber 406.

In some embodiments, which may be combined with other embodiments described herein, the first track 431 extends essentially parallel to the second track 432 through the vacuum chamber 405. The first handover assembly and the second handover assembly may be provided in opposite portions of the vacuum chamber 405, so that the first handover assembly can handle mask devices that are transported along the first track 431, and the second handover assembly 422 can handle mask devices that are transported along the second track 432. For example, the first track 431 may include an attaching position. The carrier stops in the attaching position that is shown in FIG. 6, and a mask device is attached to the carrier while the carrier remains in the attaching position. The second track 432 may include a detaching position. The carrier stops in the detaching position that is shown in FIG. 6, and a mask device is detached from the carrier while the carrier remains in the detaching position.

In some embodiments, which may be combined with other embodiments described herein, the vacuum system 400 may further include a substrate transportation system configured for transporting substrates along a substrate transportation path in the vacuum system. In particular, the substrate transportation path may extend through the vacuum chamber 405. Substrates can be transported along the substrate transportation path through the vacuum chamber 405, e.g. from a first deposition chamber which is arranged on a first side of the vacuum chamber 405 to a second deposition chamber which is arranged on a second side of the vacuum chamber.

Carriers for holding the substrates may be provided which include an electropermanent magnet assembly similar to the electropermanent magnet assembly depicted in FIG. 4A.

The vacuum chamber 405 may be arranged in a main transportation path Z of the vacuum system 400 which extends in a main transport direction (e.g. up-down direction in FIG. 6). Substrate tracks for transporting substrates and mask tracks for transporting masks may run through the vacuum chamber 405 in the main transport direction of the vacuum system 400. By inserting the vacuum chamber 405 into the main transportation path Z of the vacuum system, the vacuum chamber 405 may be used for the handling of mask devices that are used in two or more deposition chambers, particularly three or more deposition chambers, more particularly four or more deposition chambers. In some embodiments, at least two deposition chambers that are supplied with mask devices from the vacuum chamber are arranged on different sides of the vacuum chamber. Alternatively or additionally, at least two deposition chambers that are supplied with mask devices from the vacuum chamber are arranged on the same side of the vacuum chamber. In the latter case, a routing module 408 may be provided for routing the mask devices into the correct deposition chamber.

In some embodiments, which may be combined with other embodiments described herein, the main transportation path Z of the vacuum system includes four or more tracks. Further tracks may be provided. The tracks may extend parallel to each other in the main transport direction of the vacuum system. In some embodiments, said four or more tracks of the main transportation path Z may extend through the vacuum chamber 405, e.g. essentially parallel to each other. Only two tracks are depicted in FIG. 6.

In some embodiments, an evaporation source 410 may be provided in the at least one deposition chamber 406 for masked deposition of a material on the substrate. The present disclosure is however not restricted to vacuum systems with an evaporation source. For example, chemical vapor deposition (CVD) systems, physical vapor deposition (PVD) systems, e.g. sputter systems, and/or evaporation systems were developed to coat substrates, e.g. thin glass substrates, e.g. for display applications, in a deposition chamber. In typical vacuum systems, the substrates may be held by carriers, and the carriers may be transported through the vacuum chamber by a carrier transportation system. The carriers may be moved by the carrier transportation system such that at least a part of the main surfaces of the substrates are exposed toward coating devices, e.g. a sputter device or an evaporation source. The main surfaces of the substrates may be coated with a thin coating layer, while the substrates may be positioned in front of an evaporation source 410 which may move past the substrate at a predetermined speed. Alternatively, the substrate may be transported past the coating device at a predetermined speed.

The substrate may be an inflexible substrate, e.g., a wafer, slices of transparent crystal such as sapphire or the like, a glass substrate, or a ceramic plate. However, the present disclosure is not limited thereto, and the term substrate may also embrace flexible substrates such as a web or a foil, e.g. a metal foil or a plastic foil.

The substrate may be a large area substrate in some embodiments. A large area substrate may have a surface area of 0.5 m² or more. Specifically, a large area substrate may be used for display manufacturing and be a glass or plastic substrate. For example, substrates as described herein shall embrace substrates which are typically used for an LCD (Liquid Crystal Display), a PDP (Plasma Display Panel), and the like. For instance, a large area substrate can have a main surface with an area of 1 m² or larger. In some embodiments, a large area substrate can be GEN 4.5, which corresponds to about 0.67 m² substrates (0.73×0.92 m), GEN 5, which corresponds to about 1.4 m² substrates (1.1 m×1.3 m), or larger. A large area substrate can further be GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. In some implementations, an array of smaller sized substrates with surface areas down to a few cm², e.g. 2 cm×4 cm and/or various individual shapes may be positioned on a single substrate support. The mask devices may be larger than the substrates in some embodiments, in order to provide for a complete overlap with the substrates during deposition.

In some implementations, a thickness of the substrate in a direction perpendicular to the main surface of the substrate may be 1 mm or less, e.g. from 0.1 mm to 1 mm, particularly from 0.3 mm to 0.6 mm, e.g. 0.5 mm. Even thinner substrates are possible.

According to a further aspect described herein, a method of operating a vacuum system is provided. The method includes transporting a carrier 20 along a carrier transportation path in the vacuum system, while a mask device 10 or a substrate is held at the carrier 20 by a magnetic force generated by a magnet arrangement 30, particularly by an electropermanent magnet arrangement as described herein. In some embodiments, the mask device 10 is held at and transported by the carrier in a non-horizontal orientation, particularly in an essentially vertical orientation.

The magnet arrangement 30 may be an electropermanent magnet arrangement as described herein, so that reference can be made to the above explanations which are not repeated here.

The method may further include: attaching or detaching a mask device 10 or a substrate to or from a holding surface 25 of the carrier 20 by changing a magnetization of one or more first permanent magnets of the magnet arrangement 30. In particular, the polarity of the one or more first permanent magnets may be reversed by applying an electric pulse to the magnet device of the magnet arrangement.

The mask device may be handed over between a holding surface of the carrier and a holding portion of the handover assembly. In some embodiments, the magnet arrangement is attached to or integrated in a carrier body of the carrier.

In some embodiments, the mask device 10 or the substrate may be attached to the carrier 20 in the vacuum system by a handover assembly 220 that supplies the magnet arrangement with an electric pulse, e.g. from a power supply of the handover assembly. Similarly, the mask device 10 or the substrate may be detached from the carrier 20 in the vacuum system by the handover assembly 220 that supplies the magnet arrangement with an electric pulse.

The handover assembly 220 may grip and release the mask devices with a second magnet arrangement, particularly a second electropermanent magnet arrangement.

FIG. 7 is a flow diagram illustrating a method of operating a vacuum system.

In box 610, a mask device 10 to be used is loaded into a vacuum chamber with a handover assembly. The mask device may be held at a holding portion of the handover assembly by a second magnet arrangement 230 that may be provided at the holding portion of the handover assembly. The second magnet arrangement 230 may be an electropermanent magnet arrangement.

In box 620, the mask device 10 is moved toward a carrier 20 in the vacuum chamber by the handover assembly, while the second magnet arrangement 230 is in a chucking state. The mask device is moved to a holding surface of the carrier.

In box 630, the mask device is attached to the carrier 20. The second magnet arrangement 230 of the handover assembly is switched to the releasing state, and the magnet arrangement 30 of the carrier is switched to the chucking state.

In box 640, the carrier is moved along a carrier transportation path in the vacuum system, e.g. into a deposition chamber, while the mask device is held at the holding surface of the carrier.

FIG. 8 is a flow diagram illustrating a method of operating a vacuum system.

In box 710, a carrier is moved along a carrier transportation path in the vacuum system, e.g. from a deposition chamber to a further vacuum chamber, while a mask device is held at a holding surface of the carrier, particularly by a magnetic force generated by a magnet arrangement 30 as described herein.

In box 720, the mask device is detached from the carrier 20 by a handover assembly. The magnet arrangement 30 of the carrier is switched to the releasing state and the second magnet arrangement 230 of the handover assembly is switched to the chucking state, e.g. by applying respective electric pulses to the magnet arrangements.

In box 730, the mask device 10 is removed from the carrier by the handover assembly, while the second magnet arrangement 230 of the handover assembly remains in the chucking state.

In box 740, a mask device 10 is unloaded from the vacuum chamber by the handover assembly. For example, the mask device is rotated to an essentially horizontal orientation and translated through an opening in a wall of the vacuum chamber. The mask may be stored in a mask magazine in a load lock chamber, e.g. by switching to the releasing state of the second magnet arrangement 230.

While the foregoing is directed to embodiments of the disclosure, other and further embodiments of the disclosure may be devised without departing from the basic scope thereof, and the scope thereof is determined by the claims that follow.

1. A carrier for use in a vacuum system, comprising:
a magnet arrangement, including:
one or more first permanent magnets; and
one or more second permanent magnets; and
a magnet device configured to change a magnetization of the one or more first permanent magnets.

2. The carrier of claim 1, wherein the one or more first permanent magnets comprise a soft or semi-hard magnetic material, and wherein the one or more second permanent magnets comprise a hard magnetic material, particularly including neodymium.

3. The carrier of claim 1, wherein the magnet arrangement is an electropermanent magnet arrangement.

4. The carrier of claim 3, wherein the magnet device comprises a winding provided at least partially around the one or more first permanent magnets.

5. The carrier of claim 3, wherein a direction of magnetization of the one or more first permanent magnets is switchable by an electric pulse provided to the magnet device.

6. The carrier of claim 1, further comprising:
a carrier body, wherein the magnet arrangement is attached to or integrated with the carrier body, and wherein the magnet arrangement (30) is configured to hold a mask device or a substrate at a holding surface of the carrier body.

7. The carrier of claim 6, wherein the magnet arrangement is switchable between a chucking state and a releasing state, wherein, in the chucking state, the magnet arrangement generates a first external magnetic field at the holding surface, and wherein, in the releasing state, the magnet arrangement generates no external magnetic field or a second external magnetic field smaller than the first external magnetic field at the holding surface.

8. The carrier of claim 7, wherein the carrier body has an opening, and the magnet arrangement is provided at an edge of the carrier body which surrounds the opening.

9. The carrier of claim 1, further comprising a first electrical contact electrically connected to the magnet arrangement, wherein the first electrical contact is exposed at a surface of the carrier.

10. A mask device for masked deposition on a substrate, comprising an electropermanent magnet arrangement.

11. A vacuum system, comprising:
a carrier transportation system configured for transporting a carrier along a carrier transportation path in the vacuum system; and
a handover assembly configured to attach or detach a mask device or a substrate to or from a carrier with a magnet arrangement.

12. The vacuum system of claim 11, wherein the handover assembly comprises a second magnet arrangement configured to hold a mask device or a substrate at a holding portion of the handover assembly.

13. The vacuum system of claim 11, wherein the handover assembly comprises exposed second electrical contacts configured for contacting exposed first electrical contacts of the carrier for controlling the magnet arrangement of the carrier.

14. A method of operating a vacuum system, comprising:
transporting a carrier along a carrier transportation path in the vacuum system, while a mask device or a substrate is held at the carrier by a magnetic force generated by a magnet arrangement.

15. The method of claim 14, further comprising attaching or detaching a mask device or a substrate to or from a holding surface of the carrier by changing a magnetization of one or more first permanent magnets of the magnet arrangement.

16. The carrier of claim 5, wherein a polarity of the one or more first permanent magnets is reversible by the electric pulse.

17. The carrier of claim 7, wherein the magnet arrangement is configured to hold the mask device or the substrate at the holding surface in a non-horizontal or essentially vertical orientation.

18. The mask device of claim 12, wherein the electropermanent magnet arrangement is attached to or integrated into a mask frame of the mask device.

19. The vacuum system of claim 14, wherein the magnet arrangement is an electropermanent magnet arrangement.

20. The vacuum system of claim 16, wherein the second magnet arrangement is a second electropermanent magnet arrangement.
